(19) United States
(12) Patent Application Publication
(10) Pub. No.: US 2010/0280655 A1
(43) Pub. Date: Nov. 4, 2010

(54) APPARATUS, METHOD AND SYSTEM FOR DISPENSING MERCHANDISE OR INDIVIDUAL SELECTABLE VENDIBLE ITEMS

(75) Inventors: ROGER L. WILSON, URBANDALE, IA (US); FRANCIS A. WITTERN, III, WEST DES MOINES, IA (US)

Correspondence Address: MCKEE, VOORHEES & SEASE, P.L.C., 801 GRAND AVENUE, SUITE 3200, DES MOINES, IA, 50309-2721, US

(73) Assignee: FAWN ENGINEERING CORPORATION, Des Moines, IA (US)

(21) Appl. No.: 12/715,816

(22) Filed: Mar. 2, 2010

Related U.S. Application Data
(60) Provisional application No. 61/156,777, filed on Mar. 2, 2009.

(51) Int. Cl. G06F 17/00; B65D 83/00; A47F 1/04; H03M 11/00

(52) U.S. Cl. 700/231; 221/279; 221/154; 211/59.3; 221/1; 341/22

(57) ABSTRACT

An apparatus, method, and system of dispensing merchandise packaged with a hole at the top. An inventory of merchandise packaged with a hole at the top to be vended are supported on a horizontal surface. The horizontal surface is selectively actuated to provide controlled movement of each item to a dispensing location. The surface is a helically shaped member contained within a dispensing module. An electrical system operatively connects each dispensing module to a controller. The controller can be programmed to actuate movement of the surface. It can also optionally require an authorization input and/or identification input, and keep track of each dispension. This information can be stored in a manner to track usage to individuals and control inventory in the dispenser.

### CROSS-REFERENCE TO RELATED APPLICATIONS

This application claims priority under 35 U.S.C. §119 to provisional application Ser. No. 61/156,777 filed Mar. 2, 2009, which is incorporated by reference herein in its entirety.

### I. BACKGROUND OF THE INVENTION

A. Field of the Invention

The present invention relates to automated systems for dispensing items, and in particular, to dispensing from individually rotatable helix wires a wide variety of items that can be moved by the rotating helix wire, whether the item itself or packaged or suspended by a hook or hole-punched support.

B. Related Art

Automated vending machines take many forms and shapes. The technology has advanced over the years in a number of ways. The basic concept, however, remains the same. Some sort of input actuates the dispensing of an item to an access area in the vending machine.

No single vending machine or dispensing mechanism has been found satisfactory for all types of items to be vended or dispensed. For example, bottled or canned beverage vendors tend to utilize serpentine tracks to gravity feed containers individually to an access area for the customer. A single electrical or electronic actuator is all that is required to dispense single beverage containers. The serpentine track allows efficient loading of substantial inventory inside the machine. On the other hand, perishable food items such as sandwiches, desserts, fruit, and the like require more careful handling and support. In one example, rotating horizontal trays or carousels move individual items to an access position. A different but widely used dispensing mechanism rotates a helical wire coiled around a horizontal axis to push a row of product placed in between coil turns towards a drop zone. The helical wires are typically arranged in a matrix of rows and columns inside the vending machine housing. As many wires as possible are included, and the wires are as long as possible rear to front, so that as much inventory of vendible product can be loaded into the machine as possible. However, empty space or a vertical drop zone is required in front of the wires to allow vendible product from any wire to drop by gravity down to a collection or access box to retrieve the product. Typically this means that the top row of wires can extend almost all the way horizontally across the machine but the row immediately underneath is shorter so that products dropping from the row above do not hit the row below. Likewise, the next lowest row is shorter yet, and so on. This reduces the inventory capacity of the helixes. One attempt to address this is to make the wires all the same length, for part uniformity and inter-changeability, but stagger the rear ends, and associated motors and mounts, to stagger the helix front ends to allow unobstructed drops from succeedingly higher rows. But this also limits inventory capacity inside the machine, because no helix wires extend a maximum distance across the machine. These designs tilt the rear mounting plane of the helical wires to allow dispensed items to fall clear of items beneath.

A number of factors can be relevant to deciding what type of dispensing mechanism is needed or desired for dispensing a particular item or class of items, or in some cases, several different types or classes of items.

In the art it is well known to vend hole-punched products, or other items that can be dispensed by helical wires, by the foregoing method of staggering the dispensing ends of helical wires, row by row, for clearance and a free path to the dispensing bin beneath. Known vending machines which vend hole-punched or other items and/or generally make use of an inclined rear mounting plane for the rows of helical wires are U.S. Pat. No. 3,294,281 issued Dec. 27, 1966; U.S. Pat. No. 3,720,350 issued Mar. 13, 1973; and, U.S. Pat. No. 4,638,922 issued Jan. 27, 1987.

U.S. Pat. No. 3,294,281 to inventor Schlaf, incorporated by reference herein, discloses that each of the dispensing modules may be replaced individually if repair is needed. The modules include an auger-type dispensing helix or screw spindle which is rotated by a drive chain engaging all modules. The dispensing modules are removably mounted to a support panel which is forwardly inclined so that the merchandise packages have a free drop path to the dispensing bin or slot.

U.S. Pat. No. 3,720,350 to inventor Patrick, incorporated by reference herein, discloses a vending or dispensing machine having individually driven, panel-mounted, replaceable dispensing modules with theft-proof merchandise supporting and dispensing means in the form of an endless carrier belt or chain having article-dispensing projections instead of helixes. The panel which supports the dispensing modules is inclined forwardly so that the packages to be dispensed will fall freely from their module into the dispensing bin without interference from the packages on lower modules, which are of increasingly shorter length for the same purpose.

U.S. Pat. No. 4,638,922 to inventor Stoltz, incorporated by reference herein, discloses a helical vending module having dual diameter convolutions, and a vending machine equipped with a plurality of such modules. Each of the modules preferably comprises a rigid frame which is adapted to be secured to an inclined supporting surface within the vending machine. The module frame supports an outwardly projecting helical spindle coupled to an associated drive motor. The spindle includes convolutions of a first predetermined diameter along a major portion of its length, and the spindle terminates at its outwardly projecting end in integral larger diameter convolutions. The punched product to be vended is disposed between each of the adjacent convolutions when the spindle is fully loaded. A generally rectangular, rearwardly biased cover plate hinged to the module frame extends outwardly from the face plate above the spindle. The terminal end of the cover plate includes an integral, downwardly turned tab, which supports a security bar which extends toward the module frame and generally coaxially penetrates at least a portion of the larger diameter spindle convolutions to prevent products from being dislodged in response to shaking of the machine.

Each of the above-mentioned patents describes reasons why a modular type dispenser and an inclined rear mounting surface can be beneficial. Each describes why its particular solution is claimed to be beneficial. But many such existing systems tend to be complex and relatively expensive. And they tend to sacrifice inventory capacity.

### II. SUMMARY OF THE INVENTION

A. Objects of the Invention

It is therefore a principle object, feature, aspect, or advantage of the present invention to provide apparatus, methods, and systems which improve over or solve problems and deficiencies in the state of the art.

Further objects, features, advantages, and/or aspects of the present invention include an apparatus, method, or system which:
a. allows control over each individual dispensing unit.
b. allows for more efficient merchandise inventory capacity and dispensing.
c. allows for improved security of merchandise.
d. allows for faster and easier restocking of merchandise.
e. allows for faster dispensing module layout configuration or re-configuration.
f. allows for easier maintenance.
g. is conducive to tracking and controlling inventory, including consigned inventory.
h. has flexibility with regard to being easily adjustably configurable and re-configurable for different size and type products to be stored and vended.
i. promotes economy, efficiency, and reliability of parts and operation.
j. deters cheating.

B. Aspects of the Invention

One aspect of the invention comprises a dispensing apparatus with one ore more helix-based dispensing modules, each of which is adapted to store and dispense a plurality of individual items to be vended by controlled movement of each item to a dispensing location.

Another aspect of the invention comprises a dispensing module supporting tray which is motorized to allow horizontal movement for easier and more efficient dispensing from the modules.

Another aspect of the invention is a dispensing module cover retainer and pin link engaged with the helix member to, inter alia, support the distal end of the helix and discourage theft of products on the helix.

Another aspect of the invention uses a manually operably latching mechanism to hold bottom rails related to the dispensing tray in home or reference position when the assembly is in dispensing mode, but allows unlatching to allow the whole assembly to be moved forward to a restocking position for restocking the helixes more conveniently.

Another aspect of the invention uses a retainer for each helix that helps support the helix by supporting the distal end (the end away from the motor). Thus, the retainer helps make the system robust by supporting the end of the helix, as well as any products hanging or mounted on the helix.

Another aspect of the invention is a modular system configurability and layout scheme allowed by tray and dispenser unit interoperability.

Another aspect of the invention is ease of maintaining, troubleshooting, and replacing the dispensing units due to their modular design.

Another aspect of the invention comprises a system where the housing and its active components are connected to a controller where the controller can require an authorization input and/or identification input, and keeps track of each dispension. This information can be stored in a manner to track usage to individuals and control inventory in the dispenser.

### III. BRIEF DESCRIPTION OF THE DRAWINGS

FIG. 1 is a perspective partially diagrammatic view of a vending machine including an internal dispensing assembly according to one exemplary embodiment of the present invention.

FIG. 2 is an enlarged perspective view of the main support frame system which supports a plurality of motorized trays from the assembly of FIG. 1.

FIG. 3A is an enlarged perspective view of a single motorized tray for mounting a plurality of dispensing modules from the assembly of FIG. 1.

FIG. 3B is an enlarged perspective view of a single motorized tray without the dispensing modules of FIG. 1.

FIG. 3C is a right side view of a motorized tray at the home position.

FIG. 3D is a right side view of a motorized tray at the dispensing position.

FIG. 3E is a right side view of a motorized tray (top tray) at the restocking position and two other trays in the home position.

FIG. 3F is an illustration of a latching mechanism to latch a bottom rail of the tray in home or reference position.

FIG. 3G is an illustration of the latching mechanism of FIG. 3F, but in manually pivoted-up position, freeing the bottom rail to move forward to a restocking position.

FIG. 4A is an enlarged perspective view of a single dispensing module for dispensing hole-punched items from the dispensing assembly of FIG. 3B.

FIG. 4B is an isolated perspective view of a single dispensing module for dispensing hole punched items from the dispensing assembly of FIG. 3A.

FIG. 4C is an isolated view taken along line 4C-4C of FIG. 3D showing in more detail the structure to releasably connect the distal end of a helix to a cover retainer in the dispensing module.

FIG. 4D is an alternative structure to that of FIG. 4C.

FIG. 5A is an enlarged perspective view of the crank assembly from the dispensing subassembly of FIG. 3A.

FIG. 5B is a left view of the crank assembly of FIG. 5A.

FIG. 5C is a top view of the crank assembly of FIGS. 5A and 5B.

FIG. 6A is an enlarged perspective view of the switch assembly from the dispensing assembly of FIG. 3A.

FIG. 6B is a top view of the crank assembly of FIG. 3A.

FIG. 7 is a perspective view of an alternate embodiment of a motorized tray actuator.

### IV. DETAILED DESCRIPTION OF EXEMPLARY EMBODIMENTS

A. Overview

For a better understanding of the invention, specific exemplary embodiments of but a few forms the invention can take will now be described in detail. It is to be understood that these are not inclusive or exclusive of all forms and embodiments the invention can take. Frequent reference will be taken to the accompanying Figures. Reference numerals and letters will be used to indicate certain parts and locations throughout the Figures. The same reference numerals and letters will be used to indicate the same parts and locations in the Figure. unless otherwise indicated.

The context of the specific exemplary embodiments described below will be the generally horizontally moving motorized tray assembly and associated motorized dispensing module assemblies. The motorized tray comprises one or more motorized modules for dispensing merchandise. The tray(s) can be placed where needed vertically within a vending machine and the motorized modules can be placed horizontally up to 10 wide along the backplane surface of the motorized tray. Each module is applicable to a wide variety of items which are packaged with a punched hole or analogous mounting structure (e.g., hook, slot, etc.) whether on a package of the vendible item or on the vendible item. Examples are shown in patents incorporated by reference earlier.

B. Exemplary Embodiment

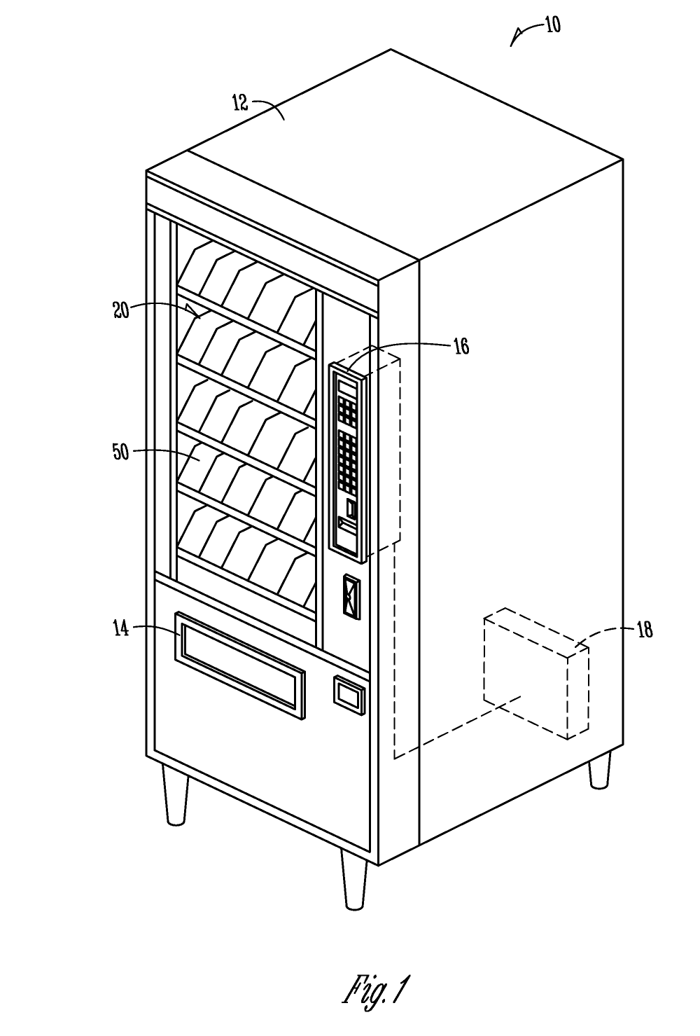

FIGS. 1, 2, 3, 4, 5 and 6 (and any sub-parts A, B, C, etc.) illustrate a dispensing machine 10 that includes one or more motorized trays 20 and product dispensing assemblies 70 for individual dispension of hole-punched items. In one form, machine 10 can essentially comprise a conventional automated merchandiser or vending machine. The external housing is approximately six foot tall by four foot deep and four foot wide. The housing can be sheet metal and is indicated generally by reference numeral 12 in FIG. 1. It can include inside helical coil dispensing modules controlled by a conventional programmable vending machine controller (VMC) 18 that instructs electric motors to rotate the helical coil of a selected product to dispense it to a drop zone where the product falls to a dispensing area, for example, a drop box 14 accessible by the customer (e.g. through an opening in the housing 12). The customer uses an input interface 16 (for example a numeric keypad) to make selections.

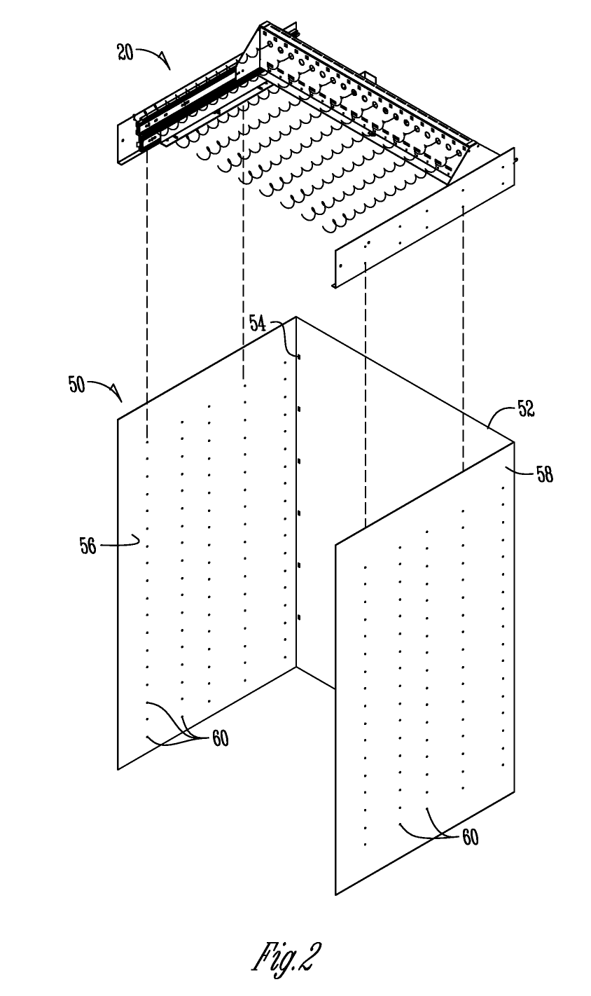

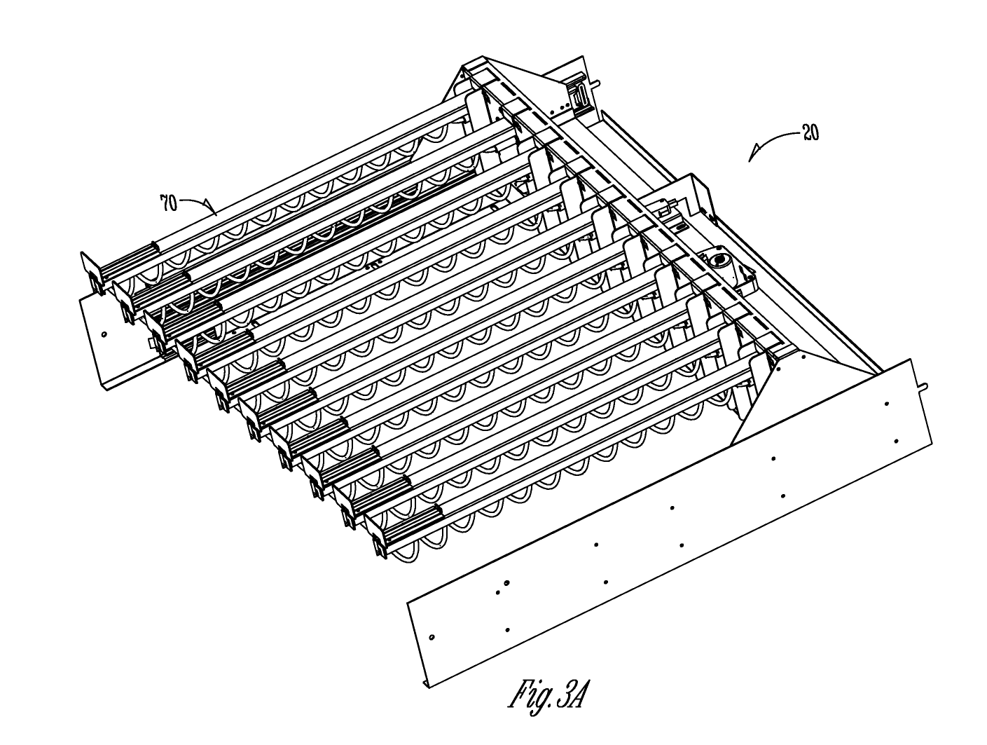

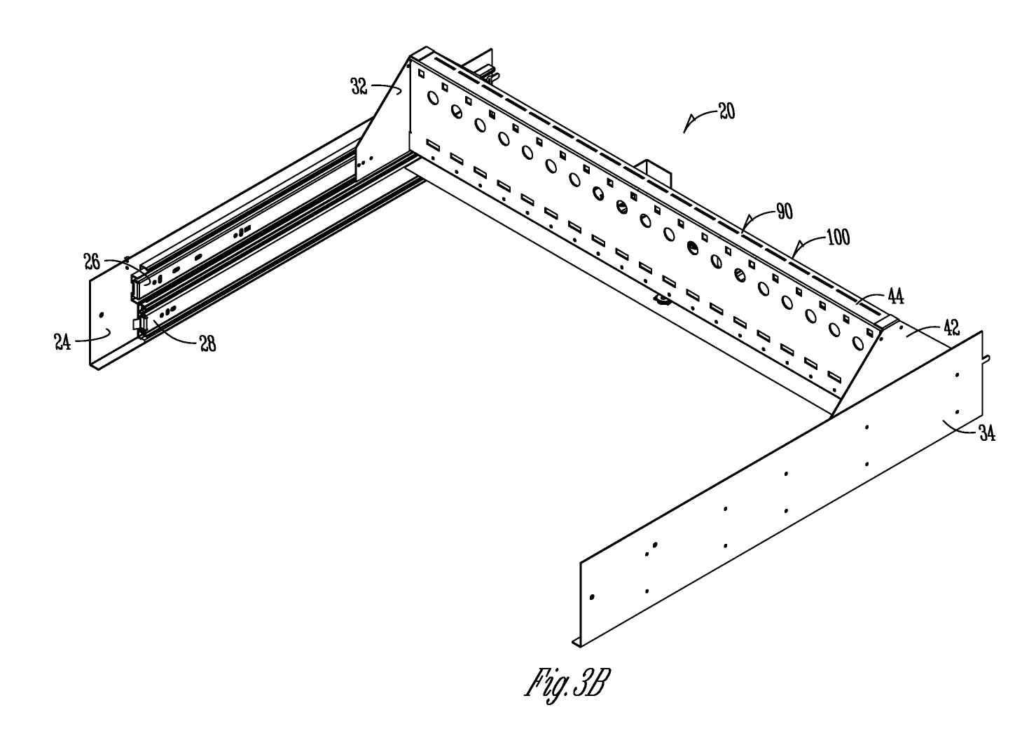

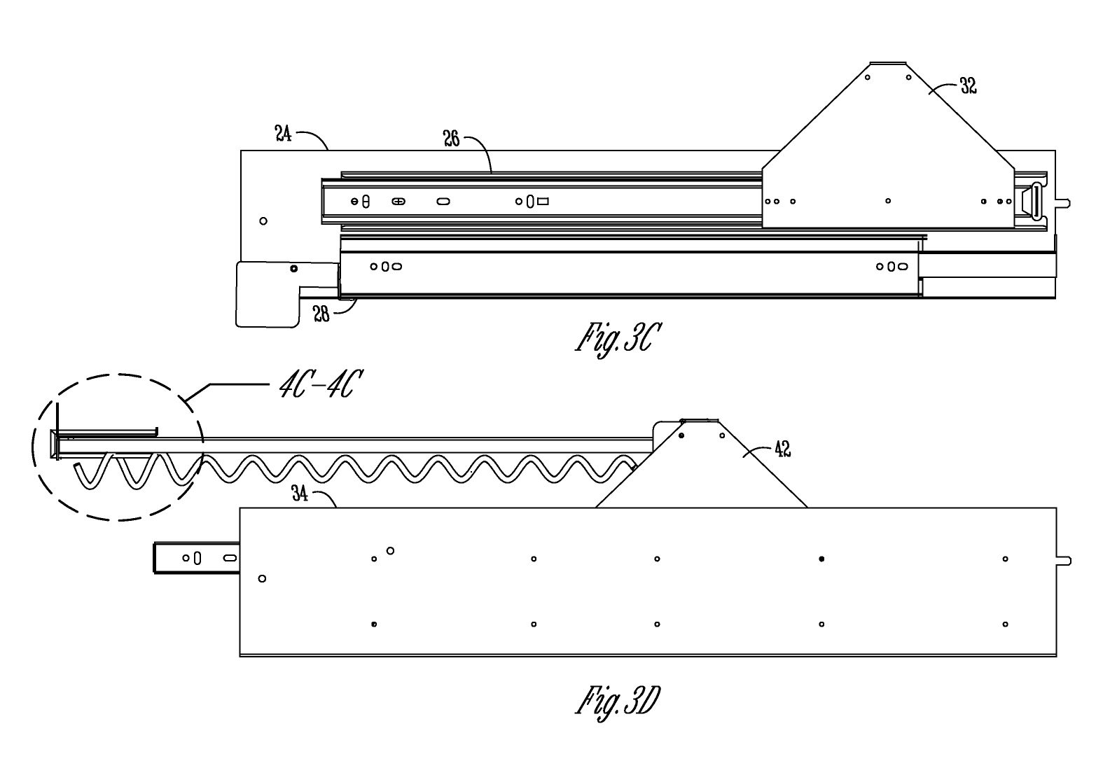

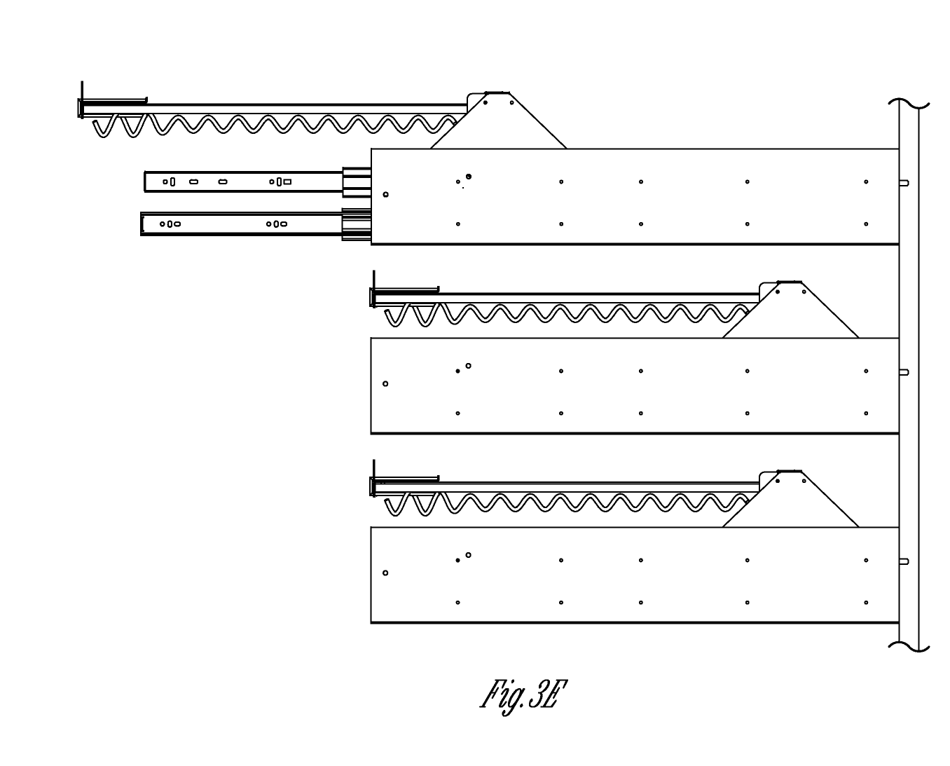

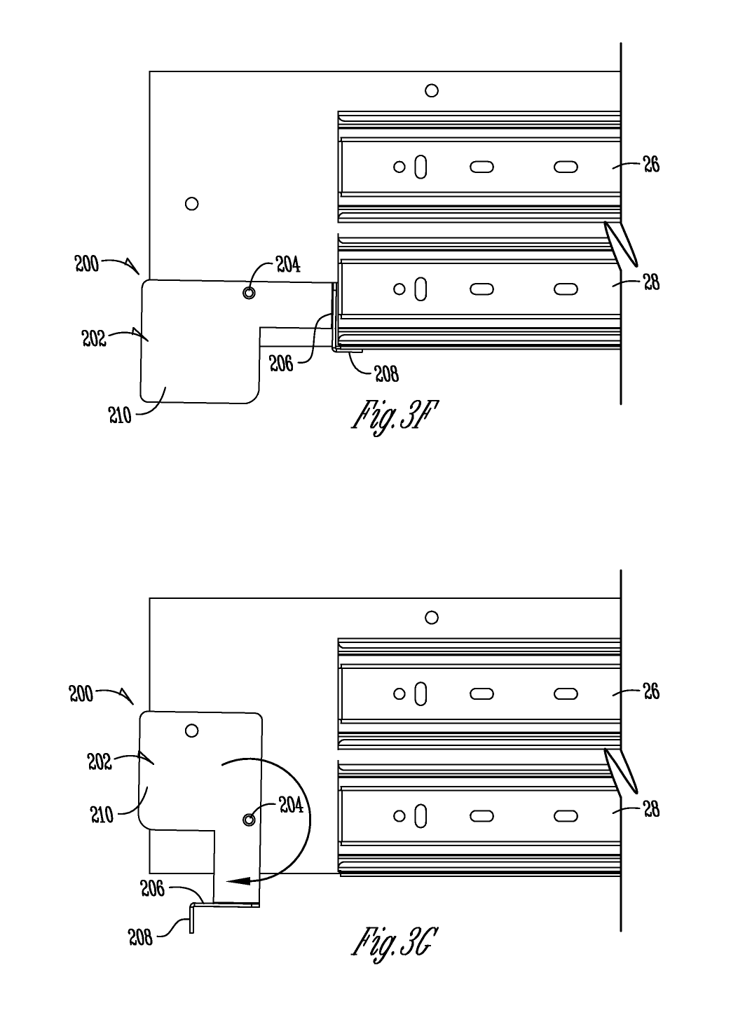

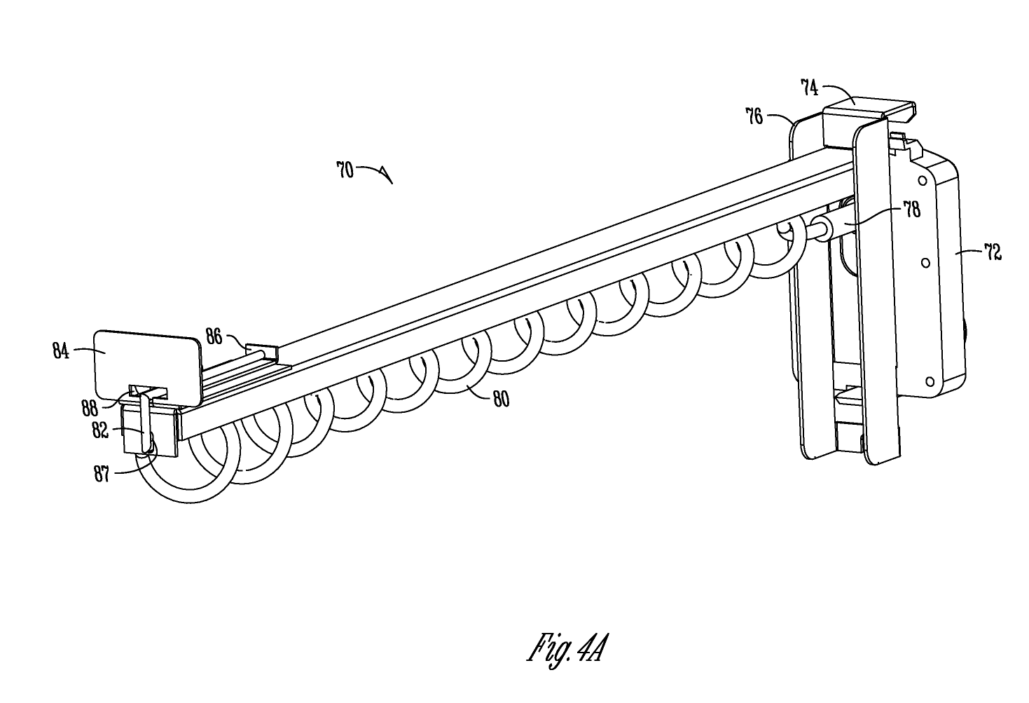

A main support frame system 50 (FIG. 2) is positioned within the dispensing machine 10 (FIG. 1). The main support frame system 50 supports a plurality of motorized trays 20 (FIG. 3A-G). The rearward retainer frame 52 has slots 54 to receive the motorized tray 20. The left and right side frames 56 and 58 have screw holes 60 which are located at equal heights to the aforementioned corresponding slots 54 to retain the motorized tray 20.

Each motorized tray 20 (FIG. 3A-G) comprises left and right slide mounts 24 and 34 fixedly attached to left and right drawer slides 26 and 36. Drawer slides 26 and 36 are fixedly attached to left and right dispensing module support frames 32 and 42. Left and right dispensing module support frames 32 and 44 are fixedly attached to attachment member 44. This allows the motorized tray 20 to move approximately six inches of forward travel for product vending.

The attachment member 44 has a total of twenty snap-in/snap-out locations for placing a motor assembly 72 and a product dispensing assembly 70. The attachment member 44 can accommodate from one to ten product dispensing assemblies 70 depending on merchandise configuration. A motor assembly 72 attaches onto the rearward vertical side of the attachment member 44. The motor assembly 72 associated with the selected product is discretely connected to a VMC or vending machine controller 18, i.e., power and control. A product dispensing assembly 70 which interfaces with motor assembly 72 attaches onto the front vertical side of the attachment member 44 for product dispensing. The motor assembly may be an electric motor assembly with a drive shaft. A crank assembly 100 and switch assembly 90 are mounted to the top horizontal side of the attachment 44 to allow horizontal movement and thus product vending. Each crank motor assembly 72 is also discretely connected to the VMC 18, i.e., power and control.

Left and right slide mounts 24 and 34 are fixedly attached to left and right roller slides 28 and 38. Roller slides 28 and 38 are fixedly attached to pusher base mounting 46.

The roller slides are known in the art to which a generalized description follows. The slide assemblies have first, second, and third track members, with the third track member being positioned between the first and second track members. The third track member has first and second U-shaped channels extending along the length thereof, with the first and second U-shaped channels having the associated open sides thereof facing the first and second track members, respectively. The first track member has first bearing means secured thereto to engage the first U-shaped channel in bearing relationship therewith, and the second track member has second bearing means secured thereto to engage the second U-shaped channel in bearing relationship therewith to enable the second and third track members to be extended and retracted with respect to the first track member.

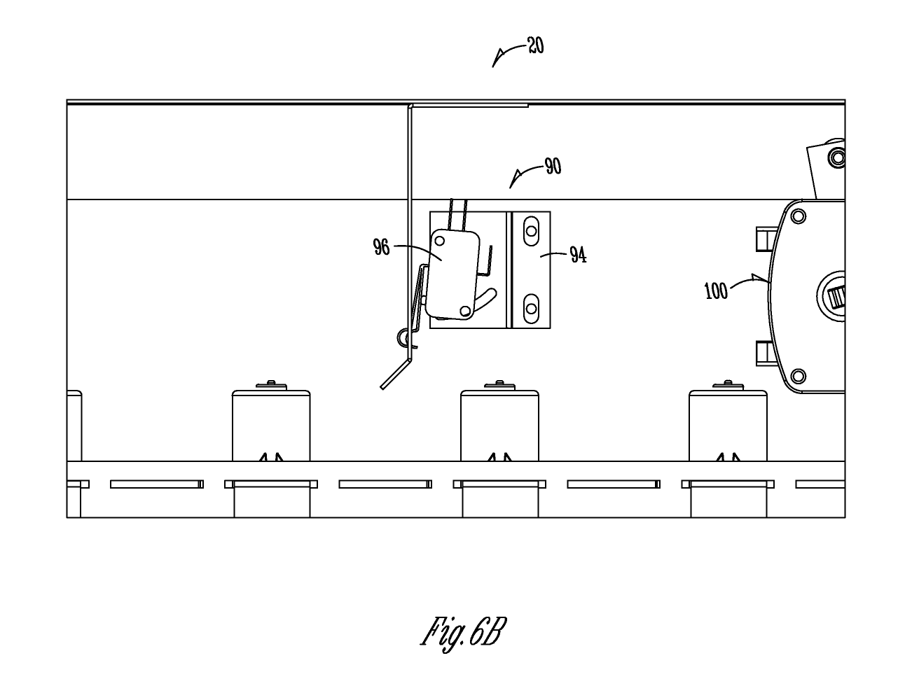

The motorized tray assembly 20 moves from its home position (FIG. 3C), the furthest rearward point within the housing 12 forward to the dispensing position (FIG. 3D) when a product has been selected via a user input inter face, such as a numeric keypad 16. The distance traveled between the home position and the dispensing position is approximately six (6) inches. Keypad 16 communicates with VMC 18 which energizes the associated tray's crank motor assembly 112, moving the attachment member 44 forward towards viewing pane 22. The crank motor assembly 112 is de-energized by VMC 18 when the selected product reaches an established vending position which is approximately six inches. The VMC 18 then energizes dispensing assembly 70 motor assembly 72 which rotates helix 80 until the product is detected in the drop box 14. VMC 18 verifies the product has been dispensed by an optical system (not shown) but described in U.S. Patent Application Publication 2005/0155977, incorporated reference herein. The helix 80 stops rotating and the attachment member 44 and crank motor assembly 112 returns to their starting positions. A switch assembly 90 (FIG. 6A-B) de-energizes the crank motor assembly 112, stopping the entire assembly at the proper position.

Latch mechanism 200 in FIGS. 3F-G is essentially a mechanical stop or block against the front edge of lower rail 28. When in the position shown in FIG. 3F, mechanism 200 prevents lower rail 28 from moving forward. Thus, only the top rails 26 (on both sides of 20) can slide forward (in accordance with operation of assembly 20 as described herein). The bottom rails (both sides of 20) cannot move forward.

Latch mechanism includes member 202, which pivots around axis 204. Plate 206 of member 202 blocks forward movement of bottom rail 28 when in the position shown in FIG. 3F. Tab 208 prevents rotation of member 202 counter-clockwise past where it is shown in FIG. 3F. Large part 210 of member 202 holds member 202 in that position of FIG. 3F by gravity when it is pivoted to the shown position.

FIG. 3G shows that a worker or operator can manually pivot 202 clockwise 90 degrees to unlatch latch mechanism 200. When unlatched, plate 206 is removed from a blocking position of rail 28. Thus, rail 28 is free to be pulled forward (and likewise can the rail 28 on the opposite side if only one latch mechanism 200 is used). This allows bottom rails 28 to slide forward a distance (until a mechanical stop not shown). In one example, it is configured to move forward about three-fourths the length of bottom rails 28 to a restocking or reloading position for assembly 20 (where the worker can more easily restock all the helixes 80 associated with top and bottom rails 26 and 28). The distance traveled from the home position to the restocking position is approximately twenty (20) inches. As mentioned earlier, when latched, top rails 26, in this example, can move forward from 4 to 6 inches (enough to allow product dropping from helixes associated with top rails 26 to drop by gravity and clear the helixes and structure associated with the bottom rails 28).

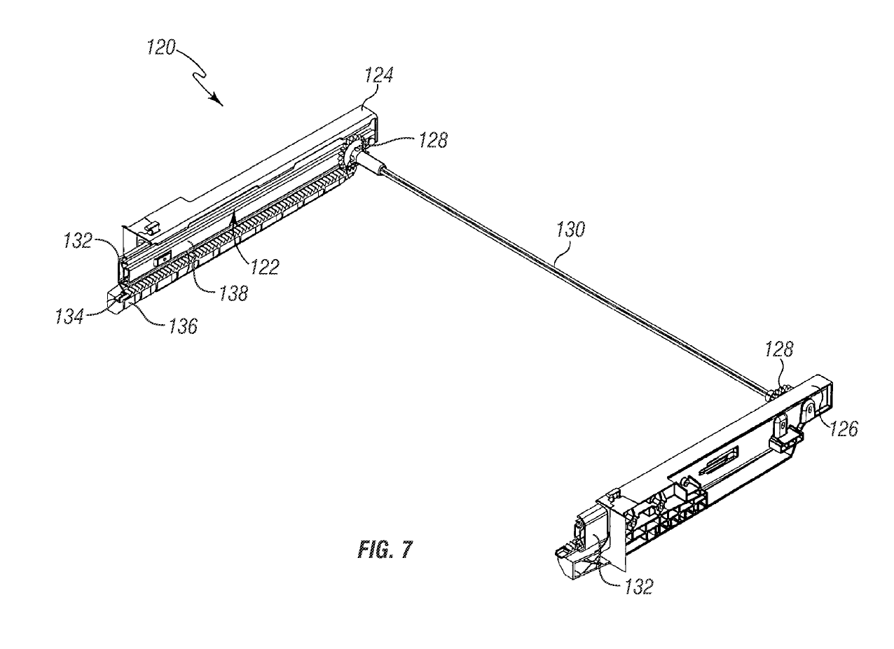

An alternative embodiment for movement of the tray is to use a rack and pinion stabilizer system 120 (FIG. 7). The rack and pinion stabilizer system comprises a pair of slide assemblies 122 attached to left and right slide mount frames 124 and 126. The slide assemblies interface with attachment member 44. A pair of gear wheels 128 having an axle 130 therebetween is also provided. The gear wheels 128 are provided in rotatable engagement with the member 44 gears and are capable of rotating in unison. Left and right rack gears 136 are provided and are positioned near the left and right slide assemblies 122. The gear wheels 128 rotate in unison along the rack gears 136. An alignment mechanism 134 is also provided. The alignment mechanism 134 is attached to at least one of the rack gears 136 for providing initial alignment of the rack gears 134 with the gear wheels 128. In one embodiment, the alignment mechanism is an L-shaped portion formed from an alignment wall section and an initial tooth of reduced height relative to a common rack tooth.

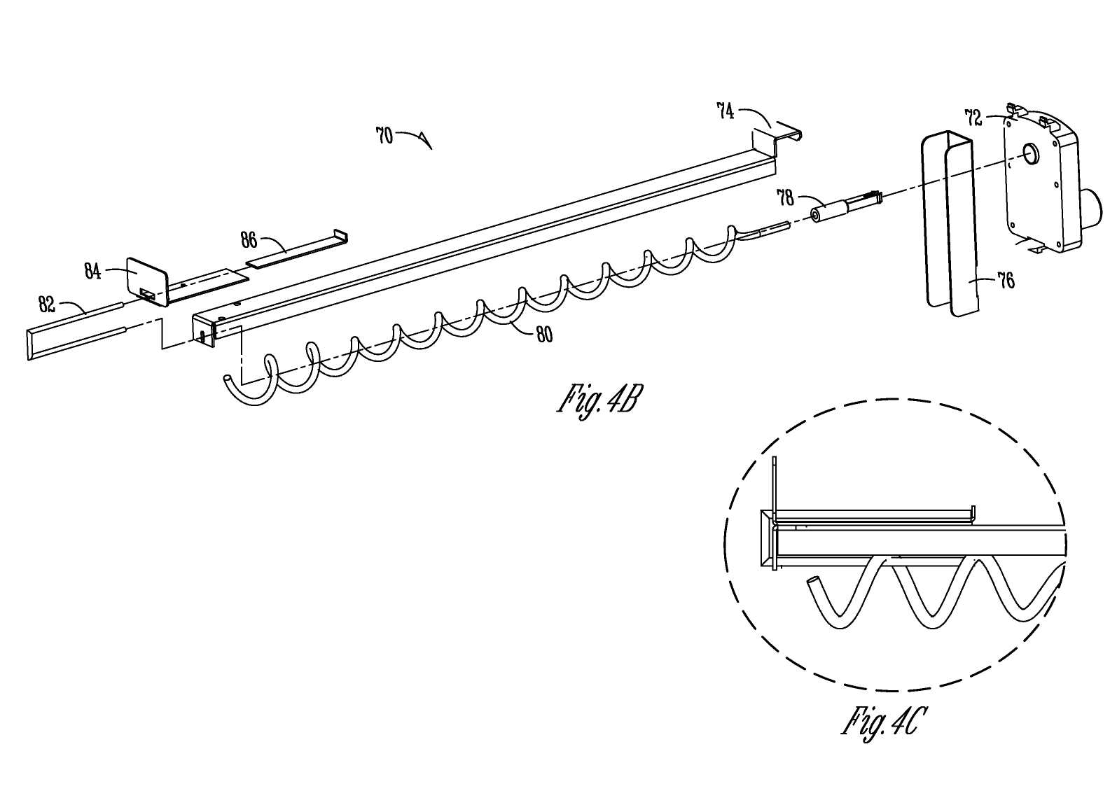

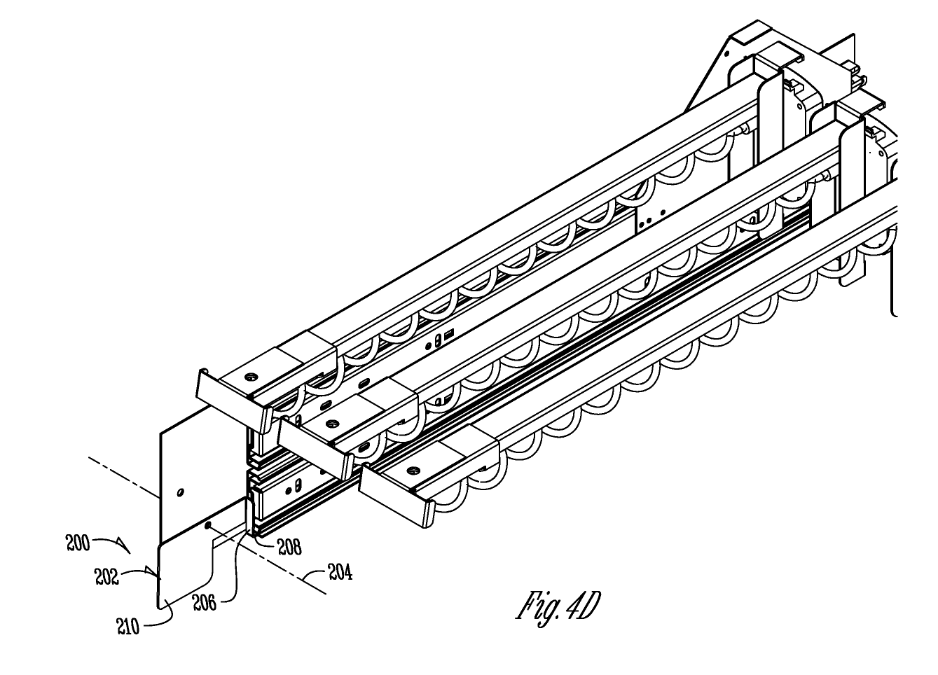

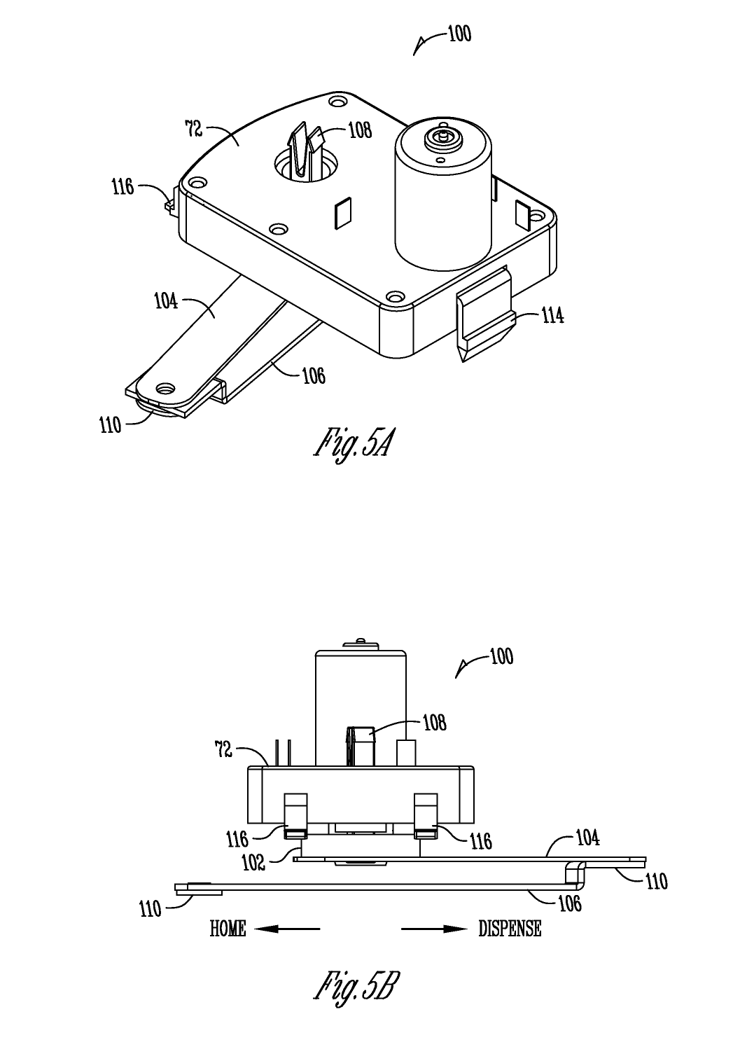

The product dispensing assembly 70 (FIG. 4A-B) comprises a motor assembly 72, a cover retainer 74, a cover retainer guard 76, a helix/motor assembly shaft 78, a helix 80, and a pin link 82, a selection label holder 84, a pin link retainer 86.

The cover retainer 74 is a structural member which, in concert with pin link 82, supports the helix 80 at its forward horizontal end, i.e., towards the viewing pane 22. When the helix 80 is at rest the pin link 82 always has at least two contact points with said helix. When vending a product, the pin link 82 has at least one contact point with the helix 80. The pin link 82 has two detents not shown which allow for dispensing and restocking. The pin link 82 is captured within slot 87 on the cover retainer 74, slot 88 on the selection label holder 84, and pin link 82. The helix 80 mates to the motor assembly 72 via shaft 78. To add or restock product to the helix, pin link 82 is slidably moved towards its forward position within the slots 87 and 88 which allows the helix 80 forward end (opposite the motor end) to drop vertically downward to allow product loading. The helix 80 has only one pitch and diameter to accommodate all product types. The cover retainer guard 76 keeps products from sliding past the helix 80 most-rearward end and onto shaft 78.

FIG. 4C is an enlarged isolation view showing more detail of how cover retainer 74 supports the distal end of its associated helix 80 (as well as anything that hangs from or is mounted along helix 80). As shown in FIG. 4C, U-shaped pin link 82 is operatively mounted in 74. The lower arm of 82 supports helix 80. When the cover retainer 74 is in dispensing and supporting position on helix 80 (as shown), the lower arm of 82 supports never less than one turn of helix 80, and can support two turns. The supported turns lay on top of lower arm of 82 and slide across that arm when the helix 80 rotates. However, pin link 82 can be manually slide forwardly of the distal end of the helix 80 to expose the distal end of helix 80 when restocking helix 80.

FIG. 4D shows an alternative way to support helix 80 on cover retainer 74. Note how this alternative and L-shaped (not U-shaped) pin link supports a helix 80 in a similar manner, and can be moved to expose the distal end of the helix 80 for restocking in a similar manner to the pin link and cover retainer of FIG. 4C.

Cover retainer 74 is a structural member, so to speak, for supporting helix 80. The assembly does not rely just on the mount of helix 80 into its associated motor.

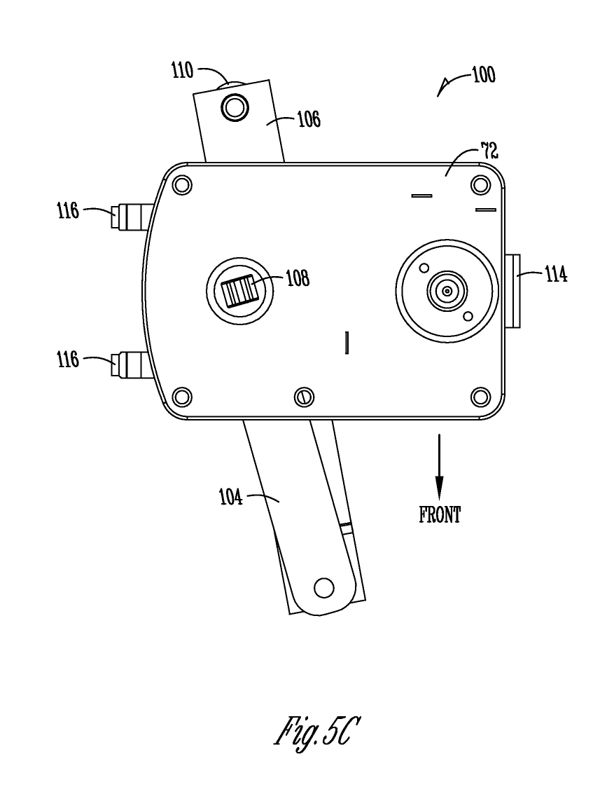

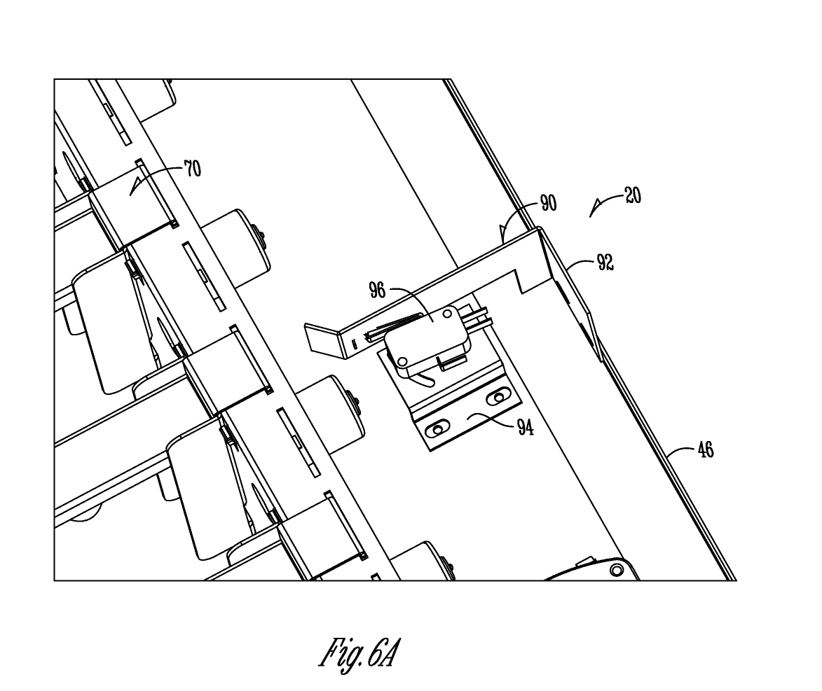

The crank assembly 100 (FIG. 5A) is operatively attached to the pusher base 46 by pusher link arm 106 via any number of conventional means (not shown). Mounting tabs 114 and 116 secure motor assembly 112 to attachment member 44. The L-shape attachment member 44 moves forward when shaft 108 turns counterclockwise forcing crank arm 104 against pusher link arm 106 to separate (FIG. 5B). Spacer bushing 110, in conjunction with a conventional securing means (not shown), operatively attach pusher link arm 106 to pusher base 46. The L-shape attachment member 44 moves rearward when shaft 108 turns clockwise forcing crank 104 against pusher link arm 106 towards each other.

As mentioned previously, VMC 18 could be appropriately programmed to operate each product dispensing assembly 70 in an appropriate manner. Some of the different methods of identifying a customer, tracking dispension, and monitoring inventory and other information related to the dispensing of products are disclosed in the earlier cited patents and publications. For example, a numeric key pad 16 on the front of the machine 10 can allow a user to identify him or her and/or identify a product by, for example, a catalog number. The software would be programmed to operate the appropriate dispenser assembly 70 to vend a single such product. Optionally the system could require an identifier and consult a database on site machine 10 or through a communications network to a remote server or database (e.g., through the internet, to authorize the customer) and/or the requested purchase.

Alternatively, there could be input mechanisms such as card scanners, or even bar code readers that could read information related to the customer or the product to be selected. The programming could have intelligence as to informing the customer if the selected product is correct for their particular job.

A variety of data usage is possible. Examples include tracking of an individual's use of a product that has been vended from the machine 10, by individual, job, department, etc., could be monitored. Inventory could be tracked and notification given as to when to restock. You could tell if the customer is selecting the right product for the job. One example would be tool or machine bits. They could be stocked by identification number in machine 10 and tracked according to the type and user identification for the person selecting the bit. Other applications or users are, of course, possible.

Further provided is a method for dispensing merchandise packaged with a hole at the top from a vending machine with a drop box, the method including the steps of: providing a plurality of motorized trays placed vertically, one on top of the other, within the vending machine; providing a plurality of dispensing modules spaced across the tray face; receiving an actuation signal from a controller; actuating the motorized tray; actuating the dispensing module; and dispensing the vendible item free from obstructions into the drop box.

Still further provided is a method for stocking a vending machine with merchandise packaged with a hole at the top, the method comprising: providing a plurality of motorized trays placed vertically, one on top of the other, within the vending machine; providing a plurality of dispensing modules spaces across the tray face; releasing a latching mechanism, wherein the motorized tray is moved from a home position to a restocking position; and stocking the dispensing modules with vendible items.

Finally, a vending machine system is provided comprising: means for holding vendible items; means for dispensing vendible items configurable to: a) receive an actuation signal; b) actuate a motorized tray; c) actuate a dispensing module; and d) dispense the vendible item free from obstructions. The holding means comprising a plurality of motorized trays placed vertically, one on top of the other, within the vending machine. The dispensing means comprising a plurality of dispensing modules spaced across the tray face.

C. Alternatives and Options

As can be appreciated, the invention can take different forms and embodiments. The embodiments described herein are not intended to limit the scope of the invention. Some examples are as follows.

One or more modules disclosed herein could be retrofitted into an existing machine that has other types of dispensers or functions. Alternatively, one or more modules could be designed for and included in an original machine that has other types of dispensers or functions. On the other hand, the machine might be dedicated to operate only one or more modules of the type disclosed herein. The machine could be a stand-alone machine or could be networked to one or more other machines.

Other options and alternatives are possible as would be obvious to those skilled in the art.

What is claimed is:

1. A vending machine for merchandise packaged with a hole at the top comprising:
a. a motorized tray with horizontal movement;
b. a dispensing module;
c. an actuator operatively connected to the motorized tray and dispensing module; and
d. a connection to the actuator adapted to receive an actuation signal from a controller.

2. The vending machine of claim 1 a plurality of motorized trays placed vertically, one on top of another, within the vending machine, the motorized tray comprising a left side member, a right side member, and an attachment member connecting the right and left side members.

3. The vending machine of claim 2 wherein the motorized tray in a dispensing mode travels from a home position to a dispensing position.

4. The vending machine of claim 3 wherein the distance from the home position to the dispensing position is equal to approximately six inches.

5. The vending machine of claim 3 wherein the motorized tray in a restocking mode travels from the home position to a restocking position.

6. The vending machine of claim 5 wherein the distance from the home position to the restocking position is equal to approximately twenty inches.

7. The vending machine of claim 5 further comprising a main support frame disposed within a vending machine external housing, the main support frame comprising:
a. a rearward retainer frame with at least one slot for receiving the motorized tray; and
b. a left side frame and a right side frame.

8. The vending machine of claim 7 wherein the left and right side members of the motorized tray are mounted within the main support frame

9. The vending machine of claim 8 wherein the attachment member of the motorized tray is slidably mounted to the left and right side members using a plurality of sliding systems.

10. The vending machine of claim 9 wherein the plurality of sliding systems include a right upper rail and a right lower rail mounted on the right side member and a left upper rail and a left lower rail mounted on the left side member and wherein the attachment member has a right glide interfacing with the right upper rail and left glide interfacing with the left upper rail.

11. The vending machine of claim 10 further comprising a pusher base, the pusher base interfacing with the right lower rail mounted on the right side member and the left lower rail mounted on the left side member.

12. The vending machine of claim 11 further comprising a latch mechanism pivotally attached to the main support frame and adjustable between a first position and a second position.

13. The vending machine of claim 12 wherein the latch mechanism in the first position allows the motorized tray to travel between the home position and dispensing position.

14. The vending machine of claim 13 wherein the latch mechanism in the second position allows the motorized tray to move travel from the home position to the restocking position.

15. The vending machine of claim 14 wherein the latch mechanism in the first position restricts movement of the left lower rail and right lower rail, the motorized tray only traveling between the home position and the dispensing position.

16. The vending machine of claim 15 wherein the latch mechanism in the second position allows for movement of the left lower rail and right lower, the motorized tray traveling between the home position and the dispensing position.

17. The vending machine of claim 16 wherein the dispensing position allows a vendible item to drop free from obstructions.

18. The vending machine of claim 17 wherein the restocking position allows for vendible items to be restocked within the motorized tray.

19. The vending machine of claim 18 wherein the latch mechanism is held in the first position by gravity and is manually pivoted to the second position.

20. The vending machine of claim 19 wherein the latch mechanism further comprises a plate, a member, and a tab.

21. The vending machine of claim 20 wherein the plate of the latch mechanism in a first position restricts movement of the motorized tray.

22. The vending machine of claim 21 wherein the tab of the latch mechanism prevents rotation of the latch mechanism past the first position.

23. The vending machine of claim 22 wherein the attachment member has a plurality of locations on a first side to receive a dispensing module and a plurality of locations on a second side commensurate with the locations on the first side, the plurality of locations on the second side adapted to receive an actuator.

24. The vending machine of claim 23 wherein a plurality of dispensing modules are placed horizontally, side-by-side, between the left side face and the right side face of the motorized tray.

25. The vending machine of claim 24 wherein the dispensing module is associated with the vendible item, the dispensing module operatively dispensing the selected vendible item when an actuation signal is received by the actuator from the controller.

26. The vending machine of claim 25 wherein the actuator comprises a motor assembly having a drive shaft interfacing with the dispensing module.

27. The vending machine of claim 26 wherein the motor assembly is connected to a controller, the controller being in further communication with a user input interface.

28. The vending machine of claim 27 wherein the user input interface is a numeric keypad.

29. The vending machine of claim 28 wherein the actuator moves the motorized tray from the home position to the dispensing position when a vendible item is selected at the user input interface, the user input interface communicating with the controller which in turn communicates with the actuator to dispense the vendible item.

30. The vending machine of claim 29 wherein the actuator operatively connected to the motorized tray is a crank assembly, the crank assembly disposed on the attachment member and connected by a pusher arm to the pusher base.

31. The vending machine of claim 30 further comprising an optical sensor in communication with the controller, the optical sensor detecting the drop of the vendible item and whereupon the controller communicates with the crank assembly to move the motorized tray from the dispensing position to the home position.

32. The vending machine of claim 31 further comprising a switch assembly, the switch assembly disposed on the attachment member and in communication with the controller, the switch assembly deactuating the crank assembly at a home position.

33. The vending machine of claim 32 further comprising a rack and pinion assembly, the rack and pinion assembly comprising:
a. first and second slide assemblies;
b. first and second rack gears positioned near the first and second slide assemblies and comprising at least one rack; and
c. first and second rotatable gear wheels in operable communication with the first and second rack gears respectively.

34. The vending machine of claim 33 wherein the spacing comprises a gear tooth drive side having a first variation from a common gear tooth profile and a gear tooth idle-side having a second variation from a common gear tooth profile.

35. The vending machine of claim 34, wherein the rack and pinion assembly interfaces with the main support frame and motorized tray.

36. A tray with horizontal movement comprising:
a. a crank;
b. a motor;
c. a plurality of dispensing module locations evenly spaced across the tray face;
d. an actuator operatively connected to the motorized tray; and
e. a connection to the actuator adapted to receive an actuation signal from a controller.

37. A dispensing module comprising:
a. a motor;
b. a helix shaped dispensing member;
c. a cover retainer which is a structural member;
d. an actuator operatively connected to the dispensing module; and
e. a connection to the actuator adapted to receive an actuation signal from a controller.

38. The dispensing module of claim 33 further comprising:
a. a cover retainer;
b. a cover retainer guard;
e. a pin link;
d. a pin link retainer; and
e. a selection label holder.

39. The dispensing module of claim 38 wherein the cover retainer and pin link remain fully engaged with the helix shaped dispensing member to discourage theft.

40. The dispensing module of claim 39 wherein the cover retainer supports a distal end of the helix shaped dispensing member.

41. A method for dispensing for merchandise packaged with a hole at the top from a vending machine with a drop box, the method comprising:
providing a plurality of motorized trays placed vertically, one on top of the other, within the vending machine;
providing a plurality of dispensing modules spaced across the tray face;
receiving an actuation signal from a controller;
actuating the motorized tray;
actuating the dispensing module; and
dispensing the vendible item free from obstructions into the drop box.

42. The method of claim 41 wherein the dispensing modules is configured to have a helix shaped dispensing member.

43. The method of claim 42 further comprising sensing the dispensing of the vendible item.

44. The method of claim 43 wherein the controller responds to a request from a user input interface.

45. The method of claim 44 wherein the controller keeps track of each dispensed item.

46. The method of claim 45 wherein the tracking of each dispensed item is associated with inventory control.

47. A method for stocking a vending machine with merchandise packaged with a hole at the top, the method comprising:
providing a plurality of motorized trays placed vertically, one on top of the other, within the vending machine;
providing a plurality of dispensing modules spaces across the tray face;
releasing a latching mechanism, wherein the motorized tray is moved from a home position to a restocking position; and
stocking the dispensing modules with vendible items.

48. A vending machine system for dispensing merchandise comprising:
means for holding vendible items;
means for dispensing vendible items configurable to:
a. receive an actuation signal;
b. actuate a motorized tray;
c. actuate a dispensing module; and
d. dispense the vendible item free from obstructions

49. The vending machine system of claim 44 wherein said holding means comprises a plurality of motorized trays placed vertically, one on top of the other, within the vending machine.

50. The vending machine of claim 45 wherein said dispensing means comprises a plurality of dispensing modules spaced across the tray face.
